(19) United States
(12) Patent Application Publication
(10) Pub. No.: US 2005/0077540 A1
(43) Pub. Date: Apr. 14, 2005

(54) Integrated circuit arrangement

(76) Inventor: Axel Hulsmann, Freiburg (DE)

Correspondence Address: MERCHANT & GOULD PC, P.O. BOX 2903, MINNEAPOLIS, MN, 55402-0903, US

(21) Appl. No.: 10/502,445

(22) PCT Filed: Jan. 24, 2003
(86) PCT No.: PCT/DE03/00256

(30) Foreign Application Priority Data
Jan. 25, 2002 (DE) 10203963.1
Mar. 28, 2002 (DE) 10214075.8

(51) Int. Cl. H01L 31/0328; H01L 31/0336; H01L 31/072

(52) U.S. Cl. 257/189

(57) ABSTRACT

The invention relates to an integrated circuit arrangement on the basis of III/V semiconductors, which comprises at least one active component (2) and a multilayer arrangement of wiring planes. A metallized layer comprising a metal contact (4) of the at least one active component (2) is configured as one of the lower wiring planes. In this manner, metallized layers that are conventionally only used for providing the metal contacts of the components, can be integrated into the wiring of the integrated circuit arrangement.

The invention relates to an integrated circuit arrangement on the basis of III/V semiconductors, comprising at least one active component and a multilayer configuration of wiring levels.

A essential criterium in assessing integrated circuit arrangements on the basis of semiconductors is the switching rate achieved by means of the circuit arrangement. It in the switching rate which determines how fast desired functions can be carried out when employing the integrated circuit arrangement. Nowadays the switching rate or fast integrated circuits on the basis of III/V semiconductors is determined largely by the type and choice of the wiring of the semiconductor components used in the integrated circuit arrangement. For instance, multilevel types of wiring techniques implemented by silicon technology are applied in wiring integrated circuit arrangements on the basis of III/V semiconductors. In other words, a plurality of wiring levels are disposed in laminated fashion on top of one another and the multilevels are interconnected by vias.

It is the object of the invention to provide an improved integrated circuit arrangement of the kind defined initially which can be produced cost effectively and with less expenditure.

This object is met, in accordance with the invention, with an integrated circuit arrangement as specified in the preamble of claim 1 in that a metallization layer comprising a metal contact of the at least one active component is formed to be a lower one of the wiring levels.

It is an essential advantage achieved by the invention over the prior art that the metallization layer which includes the metal contacts for contacting the active components in the integrated circuit arrangements is implemented, in addition, as a wiring level. The degree of integration of the circuit arrangement is improved thereby. Making the metallization layer so that it can serve as a wiring level, furthermore, offers the advantage that fewer masking levels need be employed when producing the integrated circuit arrangement. Therefore, production costs are lowered.

According to a convenient further development of the invention a passivation layer made of a material which has a small relative dielectric constant ∈r1 (∈r1<3) is applied on the metallization layer of the at least one active component. Hereby, at the same time, the electrical characteristics are optimized of the metallization layer acting as wiring level. The electrical field is concentrated mainly in the layers consisting of semiconductor materials which have a high relative dielectric constant, and it guides the electromagnetic waves generated during operation of the integrated circuit arrangement.

In a preferred embodiment of the invention an electric resistor may be formed on the lower wiring level by means of an interruption in the metallization layer. Thus an electrical component is obtained in simple manner.

Further improvement of the switching rates and a wider range of design opportunities for the integrated circuit arrangement are achieved by an advantageous modification of the invention wherein a central wiring level is disposed above the passivation layer and covered by another passivation layer made of a material which has a mean relative dielectric constant ∈r2(∈r2>∈r1, preferably ∈r2≈7).

A convenient further development of the invention may comprise an upper wiring level above the central passivation layer for further improvement of the switching properties of the integrated circuit arrangement.

The degree of integration of the semiconductor components in the integrated circuit is improved, in a further development of the invention, in that a capacitive component is formed of a section of the central wiring level and a section of the upper wiring level. It is convenient if the upper wiring level is produced by galvanic deposition of metal as this means that per se known flexibly applied precipitation techniques can be used.

A convenient embodiment of the invention may provide for the upper wiring level to be constructed at least partly by air bridge technology.

In the case of an advantageous further development of the invention the at least one active semiconductor component is a transistor, and a metal contact of the collector of the transistor is obtained by the metallization layer. Transistors are the most frequently used active components in integrated circuit arrangements and, therefore, utilizing the metallization layers of transistors as wiring levels opens a wide range of possible design layouts of wiring levels.

In an advantageous embodiment of the invention at least one microstrip conductor is formed by mans of the lower, the central, and the upper wiring levels. A new type of microstrip conductor may be created when the three wiring levels are given. Other than with the known arrangement or the sections of microstrip conductors next to one another in one plane, they now are disposed one above the other on the three wiring levels.

The designation of the wiring level formed in the metallization layer as the lower wiring level is intended to indicate the relative location with respect to the other wiring levels described in the embodiment. It does not mean that it always must be the lowest wiring level in a stack of wiring levels. The same applies to the upper wiring level. Additional wiring levels may be provided below the lower as well as above the upper wiring levels, and they may also be formed partly in metallization layers.

The invention will be decribed further, by way of example, with reference to a drawing, in which,

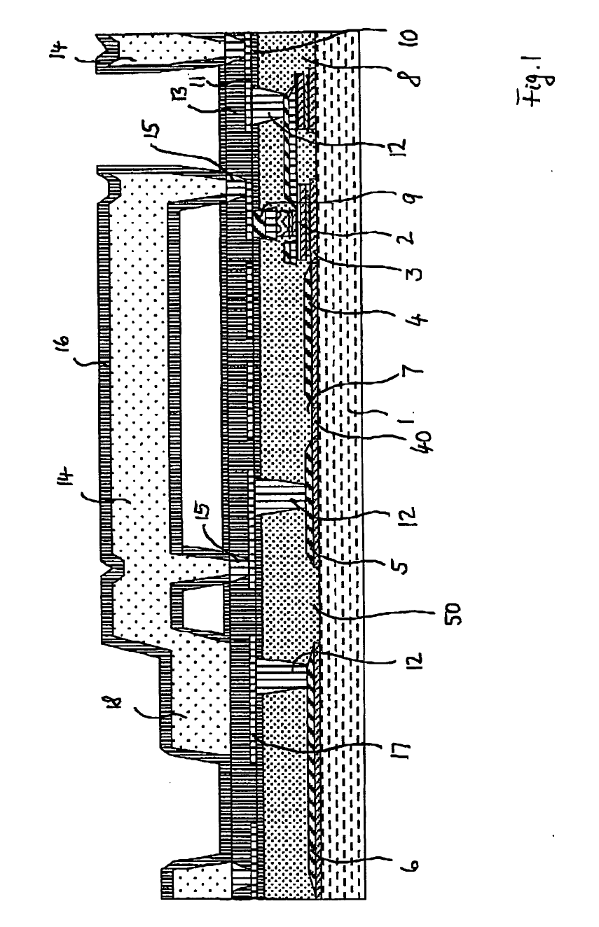

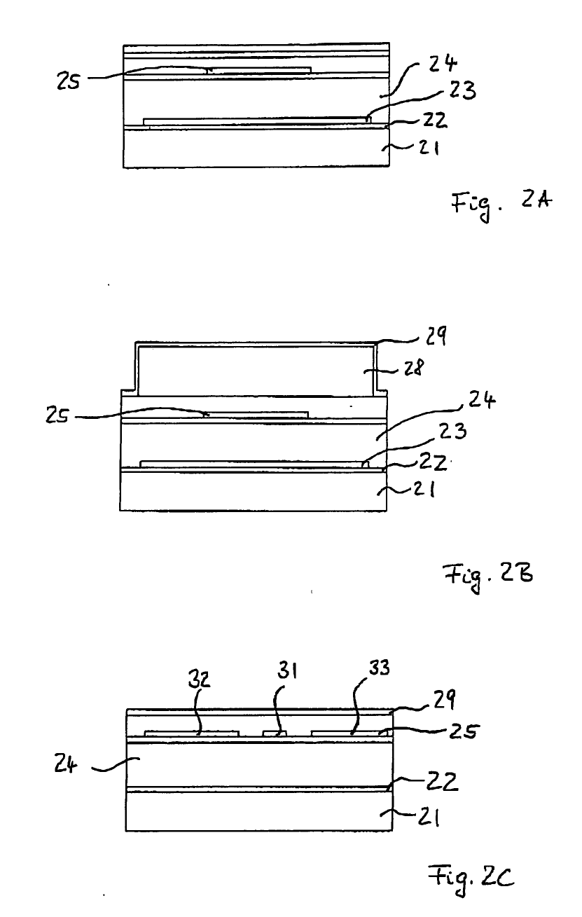

FIG. 1 is a cross sectional elevation of an integrated circuit arrangement comprising three wiring levels; and

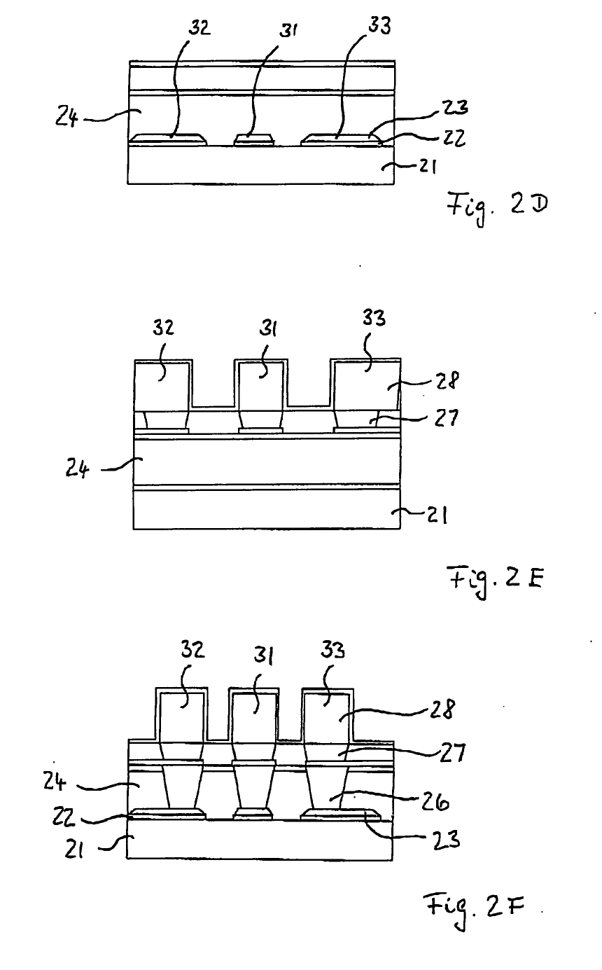

FIGS. 2A to 2F are diagrammatic illustrations of different arrangements of possible wirings for implementing high frequency waveguides.

As shown in FIG. 1, a heterobipolar transistor 2 is formed on a substrate layer 1 consisting of indium phosphate (InP). A metal contact 4 of the collector of the heterobipolar transistor 2 is provided on a subcollector layer 3 of the heterobipolar transistor 2. Further metal sections 5, 6 are formed in the layer of the metal contact 4 of the collector. Together with the further metal sections 5, 6, a lower wiring level 30 is formed in the layer of the metal contact 4. An interruption 7 between the further metal section 5 and the metal contact 4 thus presents a resistor 40.

An interruption 50 in the subcollector layer 3 and in the lower wiring level 30 make sure that neighboring leads are insulated.

Above the lower wiring level 30 including the metal contact 4 and the other metal sections 5, 6 there is a passivation layer 8. The passivation layer a covers also the heterobipolar transistor 2, the passivation layer 5 being planarized by suitable back etching in such a way that a protruding emitter metal contact 9 is obtained. The passivation layer 8 consists of a material having a low relative dielectric constant ∈r1. The low relative dielectric constant ∈r1 preferably is smaller than 3. Because of the passivation of the metal contact 4 and the other metal sections 5, 6 by means of the passivation layer 8, the whole layer including the metal contact 4 and the other metal sections 5, 6 can be used as a wiring level 30 even though, normally, the metal contact 4 serves only ad contact metal for the heterobipolar transistor. The electrical field generated during operation is concentrated mainly in the semiconductor material having a high relative dielectric constant and guides the resulting electromagnetic waves.

An end layer 10 is applied on top of the passivation layer 8; since it is optional it may be omitted in another embodiment, and it may consist of silicon nitride (SiN), SiO₂, or SiON. A central wiring level 11 which follows the end layer 10 is connected through vias 12 with the other metal sections 5, 6 and the emitter metal contact 9, respectively. The central wiring level 11 is covered by a central passivation layer 13. Like the end layer 10, the central passivation layer 13 is made, for instance, of silicon nitride having an average dielectric constant between 3 and 7.

An upper wiring level 14 is provided above the central passivation layer 13. The upper wiring level 14 is made partly in the form of air bridge construction. The upper wiring level 14 is connected electrically through vias 15 with the central wiring level 11. Optionally, the upper wiring level 24 is passivated by an upper passivation layer 16.

A section 17 of the central wiring level 11 and a section 18 of the upper wiring level 14 are positioned opposite each other, as seen in FIG. 1, whereby a capacitor is formed.

All the necessary passive components which are needed in high frequency integrated circuits, such as resistors, capacitors, coils, and air bridges for low-capacity conduit intersections can be implemented by the new, cost-efficient wiring technology described. Large area capacitances and very low ohmic leads can be used to stabilize the supply voltages.

The number of manufacturing steps and the corresponding time and costs involved are reduced by using the subcollector layer 3, the metal contact 4, and the other metal sections 5, 6 as a complete wiring level 30 as well as utilizing the upper two wiring metals for plating through to connect to the respective metallization level below. In comparison with conventional wirings, more compact circuit designs with less signal crosstalk can be obtained and, therefore, the surface area required per circuit is smaller.

The arrangement diagrammatically presented in FIG. 1 of the lower wiring level 30, the central wiring level 11, and the upper wiring level 14 above one another permits different configurations of waveguides.

FIGS. 2A to 2F are diagrammatic illustrations of different arrangements of wirings which may be employed to achieve high frequency waveguides. A partly interrupted, or totally removed, doped subcollector layer 22 which also may serve for making integrated resistors, lies on top of a semi-insulating semiconductor material 21 (e.g. InP). A passivation layer 24 made of a low dielectricity material is applied on a lower wiring level 23 and followed by a central wiring level 25 which may be connected electrically through vias 26, 27 to the lower wiring level 23 and to an upper wiring level 28. The metal of the vias 26, 27 may be identical with the associated wiring metal. A passivation layer 29 made of a material of mean dielectric value is positioned between the upper and central wiring levels 25, 28.

The novel wiring technology, comprising the use of insulation layers of different dielectric valued between the metallization levels permits high frequency waveguides of different nature to be produced simultaneously within an integrated circuit, while adapted mask geometries make it possible to obtain different wave resistances, dispersions, attenuations, phase velocities, and shielding of signals. The waveguides thus formed make room for novel switching concepts which are highly significant for maximum frequency or high bit rate integrated circuits. The relates, for example, to applications with frequencies in the order of more than 60 GHz, and data rates of more than 40 Gbit/s.

FIGS. 2A and 2B show examples of possible microstrip conduits. FIGS. 2C to 2F show ales or possible coplanar waveguides. Here, the electromagnetic wave of the high frequency signal is guided between a signal line 31 and ground lines 32, 33 (see FIGS. 2C to 2F).

The features of the invention disclosed in the specification above, in the claims, and drawing may be important for implementing the invention in its various embodiments, both individually and in any combination.

1. An integrated circuit arrangement on the basis of III/V semiconductors, comprising at least one active component (2) and a multiplayer configuration of wiring levels, characterized in that a metallization layer comprising a metal contact (4) of the at least one active component (2) is formed to be a lower one of the wiring levels.

2. The integrated circuit arrangement as claimed in claim 1, characterized in that a passivation layer (8) made of a material which has a small relative dielectric constant ∈r1 (∈r1<3) is applied on the metallization layer of the at least one active component (2).

3. The integrated circuit arrangement as claimed in claim 1, characterized in that an electric resistor is formed in the lower wiring level (30) by means of an interruption (7) in the metallization layer.

4. The integrated circuit arrangement as claimed in claim 2, characterized in that a central wiring level (11) is disposed above the passivation layer (8) and covered by another passivation layer (13) made of a material which has a mean relative dielectric constant ∈r2 (∈r2>∈r1, preferably ∈r2≈7).

5. The integrated circuit arrangement as claimed in claim 4, characterized in that an upper wiring level (14) is disposed above the central passivation layer.

6. The integrated circuit arrangement as claimed in claim 4, characterized in that a capacitive component is formed by means of a section (17) of the central wiring level (11) and a section (18) of the upper wiring level (14).

7. The integrated circuit arrangement as claimed in claim 6, characterized in that the upper wiring level (14) is formed by galvanic deposition of metal.

8. The integrated circuit arrangement as claimed in claim 6, characterized in that the upper wiring level (14) is constructed at least partly by air bridge technology.

9. The integrated circuit arrangement as claimed in claim 1, characterized in that the at least one active semiconductor component (2) is a transistor and a metal contact (4) of the collector of the transistor is formed by means of the metallization layer.

10. The integrated circuit arrangement as claimed in claim 5, characterized in that at least one microstrip conductor is formed by means of the lower, the central, and the upper wiring levels (30, 11, 14).

11. The integrated circuit arrangement as claimed in claim 1, characterized in that waveguides are formed on the lower and/or the central and/or the upper wiring levels (30, 11, 14).
